(19) United States
(12) Patent Application Publication
(10) Pub. No.: US 2003/0071633 A1
(43) Pub. Date: Apr. 17, 2003

(54) Bus fault protection unit for an electrical power system

(76) Inventors: David James Fedirchuk, Manitoba (CA); Curtis Michael Rebizant, Manitoba (CA)

Correspondence Address: ADE & COMPANY, 1700-360 MAIN STREET, WINNIPEG, MB, R3C3Z3, CA

(21) Appl. No.: 09/977,485

(22) Filed: Oct. 16, 2001

(51) Int. Cl. G01R 31/28

(52) U.S. Cl. 324/529

(57) ABSTRACT

In a three phase bus protection unit for monitoring fault conditions of an electrical power bus and actuating breakers to disconnect the associated power supply and feeder lines from the bus, there is provided for each line a current sensor responsive to the three phase currents passing through the respective breaker and the unit includes a plurality of current input terminals and a voltage input terminal for receiving the voltage output of a voltage sensor on the bus. A processor element in the unit generates digital data indicative of the instantaneous values of the voltage and of the currents and effects pre-determined algorithmic calculations on the digital values of the voltage and the currents to determine a presence of a fault condition in the current through any one of the breakers. In addition a processor element acts to sum the digital values of the currents to determine that sum of currents flowing into the bus and the sum of currents flowing. In the event that the sum differs from zero, a trip output generator trips all the circuit breakers associated with bus and records data relating to said current values. The unit is arranged such that it can be configured in a first configuration in which each of the three phases of each of up to six of the current sensors is connected to the respective current terminals and the three phases are summed independently and a second configuration in which only one of the phases from each up to eighteen of the current sensors is connected to the respective current terminals and said only one of the phases is summed.

This invention relates to a monitoring unit for use in protecting against line faults in an electrical power supply system and to a method for protection.

### BACKGROUND OF THE INVENTION

In electrical power systems it is necessary to provide breakers and to monitor for fault conditions so that the breakers can be actuated to disconnect various components of the system in the event of a fault.

The present Assignees manufacture various products such as a line protection system which receives input from one or more sensors which detect the current on the line and provide the three phase input to the protection unit. The protection unit converts the signals from the sensor into digital values of the three phases and carries out various algorithmic calculations based upon the current values and upon a voltage value to determine the present of a fault condition. In the event of a fault condition, the unit provides an output trigger which can be used to trip the breaker and/or other breakers on the same to prevent the fault condition from being transmitted to other associated power components. An example of the above device is shown in co-pending application filed on the same day as the present application under docket number 84812-302 and now Serial No. INSERT, the disclosure of which is incorporated herein by reference.

Thus equipment is available for monitoring and protecting the conditions on a power line and these are widely established and widely used both using older electro mechanical equipment and also more current equipment which uses digital calculations.

One example of an improvement of a device of this nature is shown in co-pending application entitled “MONITORING WIDE AREA DYNAMIC SWING RECORDINGS ON AN ELECTRICAL POWER SYSTEM”, filed Sep. 22, 2000, Ser. No: 09/667,582, the disclosure of which is incorporated herein by reference.

In many cases a station includes a bus arrangement to which is attached a plurality of transmission lines or feeder lines which transmit the current from the bus to end locations. The bus is attached to one or more supply lines which supply current to the bus.

In many cases the individual line protection is considered satisfactory to provide protection for the system at the station.

In other cases utilizing the conventional electromechanical systems and utilizing high impedance current detection systems, attempts have been made to provide additional protection for the bus itself to ensure that no faults on the bus can cause a breakdown of the system which could be transmitted to other parts of the grid. In situations where the bus itself is relatively long and complex, enhanced protection for the bus is more important.

Up till now, however, no digital equipment has been available for monitoring the bus to ensure that any fault developing on the bus itself is properly controlled by tripping the necessary breakers.

### SUMMARY OF THE INVENTION

It is one object of the present invention therefore to provide an improved monitoring unit and an improved method using that unit.

According to one aspect of the invention there is provided an apparatus for monitoring current flow in a power supply bus of a three phase electrical power system and for controlling circuit breakers to provided protection for the system, the system comprising:

a power supply bus;

at least one three phase power supply line connected to the bus for supplying current thereto;

at least one three phase power feeder line connected to the bus for receiving current therefrom;

a plurality of circuit breakers each connected between a respective one of the supply and feeder lines and the bus for disconnecting flow of current therebetween;

a plurality of current sensors each responsive to the three phase current flow between the bus and a respective one of the supply and feeder lines to provide three outputs indicative of the A-phase, B-phase and C-phase respectively of the three phase current flow;

and a voltage sensor responsive to the voltage on the bus to provide a voltage output indicative thereof;

the apparatus comprising a monitoring and control unit associated with a respective one of the lines having:

a plurality of current input terminals;

a voltage input terminal for receiving the voltage output of the voltage sensor;

a processor element in the unit responsive to the outputs from the terminals for generating digital data indicative of the instantaneous values of the voltage and of the currents;

a processor element in the unit for effecting pre-determined algorithmic calculations on the digital values of the voltage and the currents to determine a presence of a fault condition in the current through any one of the breakers;

a processor element for summing the digital values of the currents to determine that sum of currents flowing into the bus and the sum of currents flowing from the bus is equal to zero and for determining a fault condition in the event that the sum is not equal to zero.

a trip output generator for generating a trip output in response to said fault condition for tripping all the circuit breakers associated with bus;

and recording means for recording data relating to said current values in the event of a fault condition.

Preferably the unit is arranged such that it can be configured in a first configuration and in a second configuration, wherein in the first configuration each of the three phases of each of the current sensors is connected to the respective current terminals and the three phases are summed independently and wherein in the second configuration only one of the phases from each of the current sensors is connected to the respective current terminals and said only one of the phases is summed.

Preferably the number of current input terminals on the unit is at least 18.

Preferably the number of current input terminals on the unit is at least 18 and wherein the unit is arranged such that it can be configured in the first configuration to receive the three phases from 6 lines and in the second configuration to receive a single phase from 18 lines.

According to a second aspect of the invention there is provided a method comprising:

providing a power supply bus;

connecting at least one three phase power supply line to the bus for supplying current thereto;

connecting at least one three phase power feeder line to the bus for receiving current therefrom;

locating between a respective one of the supply and feeder lines and the bus a respective one of a plurality of circuit breakers for disconnecting flow of current therebetween;

providing a plurality of current sensors each responsive to the three phase current flow between the bus and a respective one of the supply and feeder lines to provide three outputs indicative of the A-phase, B-phase and C-phase respectively of the three phase current flow;

providing a voltage sensor responsive to the voltage on the bus to provide a voltage output indicative thereof;

providing a monitoring and control unit for the bus;

providing on the unit a plurality of current input terminals and connecting thereto a respective one of the three outputs of the current sensors;

providing on the unit a voltage input terminal for receiving the voltage output of the voltage sensor;

in the unit generating digital data indicative of the instantaneous values of the voltage and of the currents in response to the outputs from the terminals;

in the unit effecting pre-determined algorithmic calculations on the digital values of the voltage and the currents to determine a presence of a fault condition in the current through any one of the breakers;

in the unit summing the digital values of the currents to determine that, for each of the A-phase, B-phase and C-phase separately, the sum of currents flowing into the bus and the sum of currents flowing from the bus is equal to zero;

generating a fault condition in the event that the sum is not equal to zero;

generating a trip output in response to said fault condition for tripping all the circuit breakers associated with bus;

and recording data relating to said current values in the event of a fault condition.

According to one arrangement, the bus is supplied by a transformer and wherein there is provided a current sensor responsive to current which is connected either upstream of the transformer or between the transformer and the bus and provides an input to the unit.

Alternatively, the bus is supplied by a transformer and wherein there is provided a first current sensor responsive to current which is connected upstream of the transformer and a second current transformer between the transformer and the bus each of which provides an input to the unit.

Preferably the number of current input terminals on the unit is at least 18 and wherein the unit is arranged such that it receives each of the three phases from 6 lines.

According to a third aspect of the invention there is provided a method comprising:

providing a power supply bus;

connecting at least one three phase power supply line to the bus for supplying current thereto;

connecting at least one three phase power feeder line to the bus for receiving current therefrom;

locating between a respective one of the supply and feeder lines and the bus a respective one of a plurality of circuit breakers for disconnecting flow of current therebetween;

providing a plurality of current sensors each responsive to the three phase current flow between the bus and a respective one of the supply and feeder lines to provide three outputs indicative of the A-phase, B-phase and C-phase respectively of the three phase current flow;

providing a voltage sensor responsive to the voltage on the bus to provide a voltage output indicative thereof;

providing a first, a second and a third separate monitoring and control units for the bus;

providing on each of the units a plurality of current input terminals;

connecting to the current input terminals of the first unit a respective one of the A-phase outputs of the current sensors;

connecting to the current input terminals of the second unit a respective one of the B-phase outputs of the current sensors;

connecting to the current input terminals of the third unit a respective one of the B-phase outputs of the current sensors;

providing on each of the units a voltage input terminal and connecting thereto the voltage output of the voltage sensor;

in each of the units generating digital data indicative of the instantaneous values of the voltage and of the currents in response to the outputs from the terminals connected thereto;

in each of the units effecting pre-determined algorithmic calculations on the digital values of the voltage and the currents to determine a presence of a fault condition in the current through any one of the breakers;

in the first unit summing the digital values of the currents to determine that for the A-phase the sum of currents flowing into the bus and the sum of currents flowing from the bus is equal to zero;

in the second unit summing the digital values of the currents to determine that for the B-phase the sum of currents flowing into the bus and the sum of currents flowing from the bus is equal to zero;

in the third unit summing the digital values of the currents to determine that for the C-phase the sum of currents flowing into the bus and the sum of currents flowing from the bus is equal to zero;

in each of the units generating a fault condition in the event that the sum is not equal to zero;

in each of the units generating a trip output in response to said fault condition for tripping all the circuit breakers associated with bus;

and recording data relating to said current values in the event of a fault condition.

Preferably each unit has at least 18 current input terminals for receiving one of the phases from the same number of lines.

### BRIEF DESCRIPTION OF THE DRAWINGS

One embodiment of the invention will now be described in conjunction with the accompanying drawings in which:

FIG. 1 is a schematic illustration of a scheme according to the present invention for protecting a bus against faults in a three phase electrical power system which has a limited number of lines connected to the bus allowing protection by a single unit.

FIG. 2 is a similar schematic illustration of a scheme according to the present invention for protecting a bus against faults in a three phase electrical power system which has a larger number of lines connected to the bus thus requiring protection by three units each associated with a respective phase.

FIG. 3 is a schematic illustration of one example of the Bus protection unit of FIG. 1 showing examples of the specific algorithms and protection elements according to the known IEEE standard for such elements.

### DETAILED DESCRIPTION OF PREFERRED EMBODIMENTS

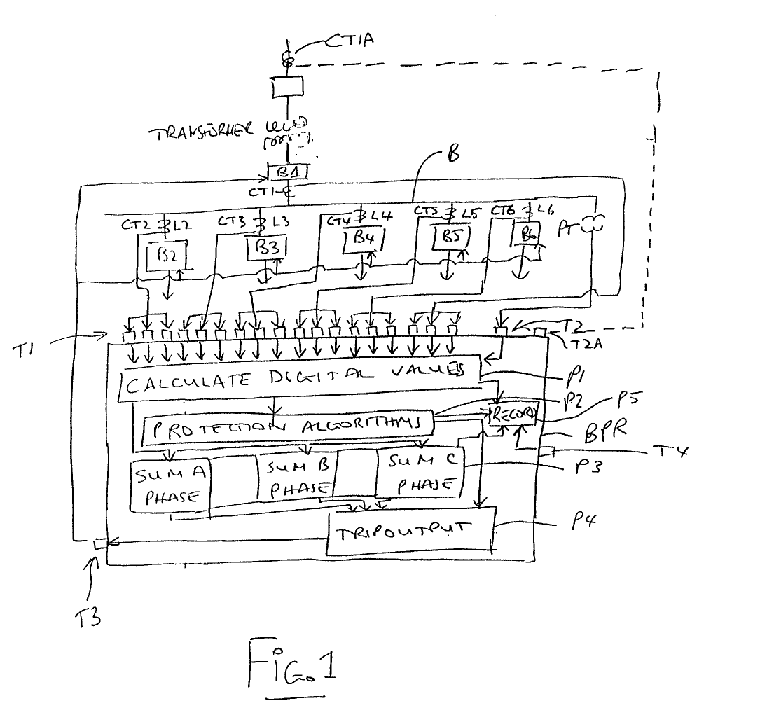

In FIG. 1 is shown a bus system of an electric power supply network where the bus is indicated at B and connects to six lines L1 through L6. L1 acts as a supply line from a transformer, generator or the like and the lines L2 through L6 are feeder lines to remote locations. The bus is supplied by a transformer.

Between each line and the bus is provided a breaker B1 through B6. A current transformer is provided for detecting the current flowing between the bus and the line so that there are similarly six current transformers CT1 through CT6.

It will be appreciated that the system shown in merely one example and the number of lines may differ and also the arrangement of the line that is the number of supply lines relative to the number of feed lines may differ.

A protection relay BPR is provided which has eighteen current inputs indicated at Terminal T1, an input T2 for receiving a signal representative of the voltage on the bus as indicated at PT and a plurality of output terminals indicated at T3.

In the arrangement shown the eighteen current input terminals at T1 are divided into six sets of three terminals so that the three phase current inputs from the current transformers CT1 through CT6 are supplied respectively to each of the sets of three terminals. In this way the relay receives signals relating to the current on each of the six lines together with the voltage at T2.

A first processor component P1 is provided which acts to convert the input signals from the terminals to the digital values of the individual currents and voltage.

In a second processor component P2 there is provided a series of protection algorithms which act to detect various parameters of the currents and voltage to determine a fault condition.

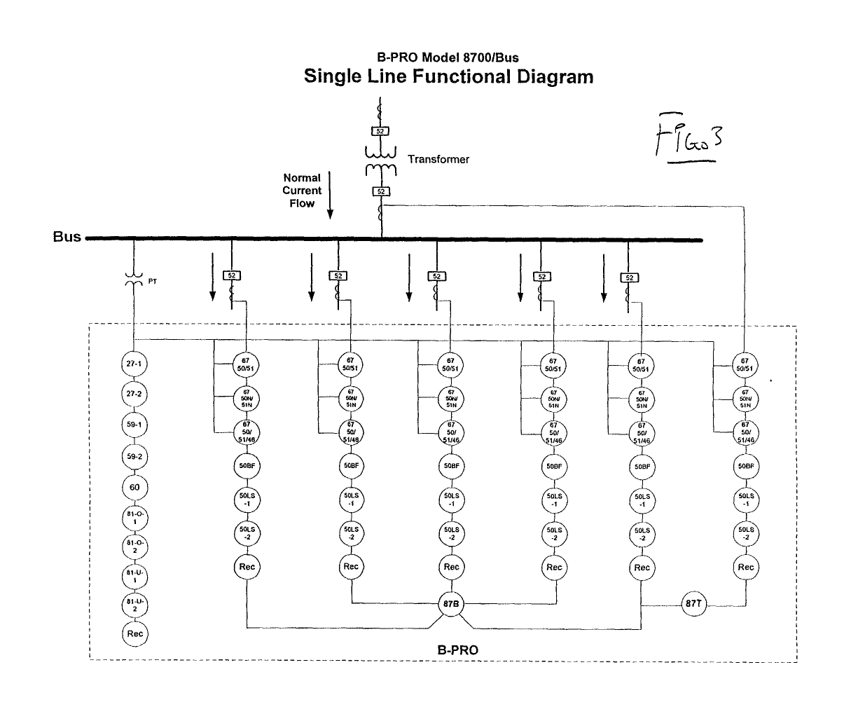

In FIG. 3 is shown the series of protection algorithms which are calculated and these numbers are taken from the IEEE standard C37.2-1979 which defines the protection functions.

In a third processor component P3 the digital values of individual currents are summed so as to effect a sum of the A phase components, the B phase components and the C phase components separately. The sum takes into account the phase angle of the currents so that it acts as a differential calculation to determine the total current flowing into and out of the bus B. It will of course be appreciated that the current flow should equal 0 for each of the three separate phases and in the event that the sum does not equal 0 then a fault condition has developed.

The output from the processor component P2 in the event that detection of a fault condition and the output from the processor component P3 in the event of a detection of a fault condition dependent upon one of the sums being different from 0 provides an output to a further processing component P4 which acts as a trip output for supply to the output terminal T3.

The output terminal T3 provides a trip signal which is communicated to each of the breakers B1 through B6 to effect a tripping action of the whole of the current flow on the bus in the event of detection of a fault condition as set forth above.

After generation of a trip output to each of the breakers, the current through the respective current transformer CT1 through CT6 continues to be monitored for detection of a current which is different from zero, in which condition a breaker failure is detected. If a breaker failure is detected, action by the monitoring device is needed to clear the faulted line from the power system by tripping breakers next to the failed breaker. The unit can also be configured where the current transformer CT1 is located as shown in dash line at CT1A. The unit can also be configured using an additional input T2A to receive current from both transformers CT1 and CT1A. This arrangement can be used to provide a differential protection zone for the bus B and/or for the incoming transformer “Trans”. The protection system can then detect the area where the fault is located and isolate that protection area from the power supply system by tripping the appropriate breakers.

The unit also includes a recording component P5 which acts to record the digital values of the currents and voltage in the event of a fault condition being detected.

Attention is also directed to copending application Ser. No. 09/667,582 filed Sep. 22, 2000 which discloses a time stamp and sample syncronization recording system and the unit includes a terminal T4 which allows communication from an outside source to effect the recording action and is entitled “MONITORING WIDE AREA DYNAMIC SWING RECORDINGS ON AN ELECTRICAL POWER SYSTEM”.

The relay unit therefore provides the following functions.

It provides bus differential protection, that is the summing action of the currents to ensure that the sum is zero in all conditions thus detecting bus faults independently of line faults.

It includes integrated breaker failure detection in that the status of the current through the breakers is determined in the event of breaker action.

The algorithms can include over current protection functions from the IEEE standard.

The recording system allows the digital values of the currents to be recorded for metering the action of the bus and for fault oscillography.

The algorithms applied to the voltage values can be used to detect over/under bus voltage as well as over/under frequency functions.

The unit can save costs by using the same current transformers used by other relays in the system thus minimizing external wiring and eliminating the need for some special current transformers.

The unit provides metering functions for each line connection.

The unit includes off line analysis and setting software for viewing fault records and creating relay settings offline. Th is feature allows for the further analysis of events and fault conditions that have taken place during a particular fault condition.

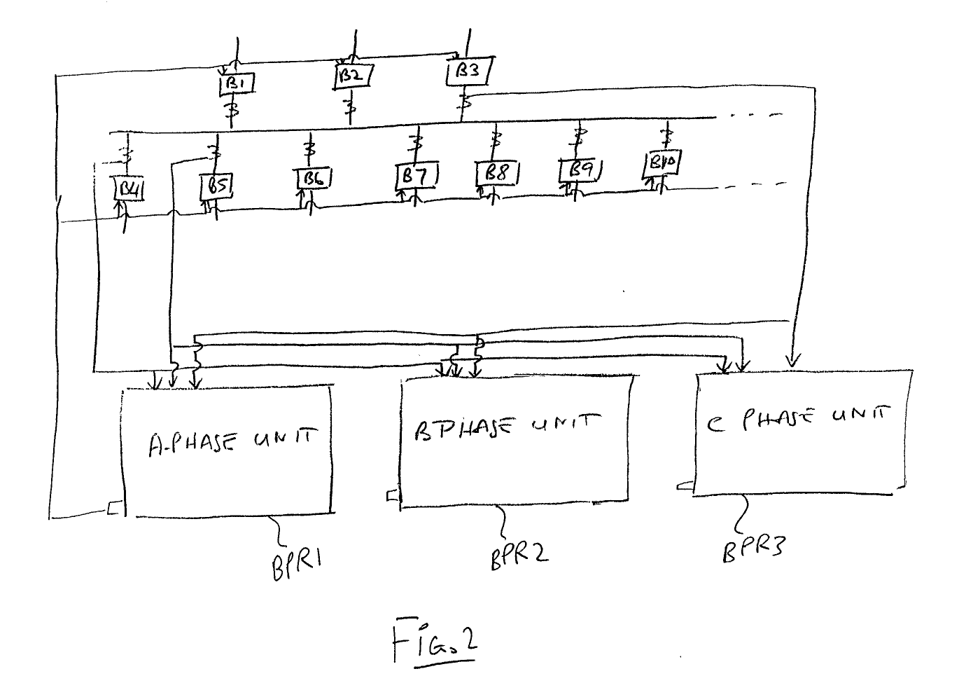

Turning now to FIG. 2 three of the same units shown in FIG. 1 and shown in FIG. 3 are used as indicated at BPR1, BPR2 and BPR3. In this arrangement the units are configured so that each is associated with a respective one of the three phases of the bus system. Thus in this case the total number of lines is greater than 6 and may be up to 18 so that each current transformer supplies a signal indicative of the individual three phases to the terminals T1 of the three units. Thus BPR 1 receives all the A phases, BPR2 receives all of the B phase and BPR3 receives all the C phases

The same protection functions and the same summation are carried out in each of the units so that for example the unit BPR1 acts to sum the A phase currents of all of the lines to ensure that the net current on the bus is 0.

The units can be readily reconfigured by software input to accommodate either the scheme of FIG. 1 of the scheme of FIG. 2.

When the protection device is used as in FIG. 2, a software setting is invoked that allows each unit device to function as by adding individual phase quantities instead of breaker currents.

Since various modifications can be made in my invention as herein above described, and many apparently widely different embodiments of same made within the spirit and scope of the claims without department from such spirit and scope, it is intended that all matter contained in the accompanying specification shall be interpreted as illustrative only and not in a limiting sense.

1. Apparatus for monitoring current flow in a power supply bus of a three phase electrical power system and for controlling circuit breakers to provided protection for the system, the system comprising:
a power supply bus;
at least one three phase power supply line connected to the bus for supplying current thereto;
at least one three phase power feeder line connected to the bus for receiving current therefrom;
a plurality of circuit breakers each connected between a respective one of the supply and feeder lines and the bus for disconnecting flow of current therebetween;
a plurality of current sensors each responsive to the three phase current flow between the bus and a respective one of the supply and feeder lines to provide three outputs indicative of the A-phase, B-phase and C-phase respectively of the three phase current flow;
and a voltage sensor responsive to the voltage on the bus to provide a voltage output indicative thereof;
the apparatus comprising a monitoring and control unit associated with a respective one of the lines having:
a plurality of current input terminals;
a voltage input terminal for receiving the voltage output of the voltage sensor;
a processor element in the unit responsive to the outputs from the terminals for generating digital data indicative of the instantaneous values of the voltage and of the currents;
a processor element in the unit for effecting pre-determined algorithmic calculations on the digital values of the voltage and the currents to determine a presence of a fault condition in the current through any one of the breakers;
a processor element for summing the digital values of the currents to determine that sum of currents flowing into the bus and the sum of currents flowing from the bus is equal to zero and for determining a fault condition in the event that the sum is not equal to zero.
a trip output generator for generating a trip output in response to said fault condition for tripping all the circuit breakers associated with bus;
and recording means for recording data relating to said current values in the event of a fault condition.

2. The apparatus according to claim 1 wherein the unit is arranged such that it can be configured in a first configuration and in a second configuration, wherein in the first configuration each of the three phases of each of the current sensors is connected to the respective current terminals and the three phases are summed independently and wherein in the second configuration only one of the phases from each of the current sensors is connected to the respective current terminals and said only one of the phases is summed.

3. The apparatus according to claim 1 wherein the number of current input terminals on the unit is at least 18.

4. The apparatus according to claim 2 wherein the number of current input terminals on the unit is at least 18 and wherein the unit is arranged such that it can be configured in the first configuration to receive the three phases from 6 lines and in the second configuration to receive a single phase from 18 lines.

5. A method comprising:
providing a power supply bus;
connecting at least one three phase power supply line to the bus for supplying current thereto;
connecting at least one three phase power feeder line to the bus for receiving current therefrom;
locating between a respective one of the supply and feeder lines and the bus a respective one of a plurality of circuit breakers for disconnecting flow of current therebetween;
providing a plurality of current sensors each responsive to the three phase current flow between the bus and a respective one of the supply and feeder lines to provide three outputs indicative of the A-phase, B-phase and C-phase respectively of the three phase current flow;
providing a voltage sensor responsive to the voltage on the bus to provide a voltage output indicative thereof;
providing a monitoring and control unit for the bus;
providing on the unit a plurality of current input terminals and connecting thereto a respective one of the three outputs of the current sensors;
providing on the unit a voltage input terminal for receiving the voltage output of the voltage sensor;
in the unit generating digital data indicative of the instantaneous values of the voltage and of the currents in response to the outputs from the terminals;
in the unit effecting pre-determined algorithmic calculations on the digital values of the voltage and the currents to determine a presence of a fault condition in the current through any one of the breakers;
in the unit summing the digital values of the currents to determine that, for each of the A-phase, B-phase and C-phase separately, the sum of currents flowing into the bus and the sum of currents flowing from the bus is equal to zero;
generating a fault condition in the event that the sum is not equal to zero;
generating a trip output in response to said fault condition for tripping all the circuit breakers associated with bus;
and recording data relating to said current values in the event of a fault condition.

6. The method according to claim 5 wherein the bus is supplied by a transformer and wherein there is provided a current sensor responsive to current which is connected either upstream of the transformer or between the transformer and the bus and provides an input to the unit.

7. The method according to claim 5 wherein the bus is supplied by a transformer and wherein there is provided a first current sensor responsive to current which is connected upstream of the transformer and a second current transformer between the transformer and the bus each of which provides an input to the unit.

8. The method according to claim 5 wherein the number of current input terminals on the unit is at least 18 and wherein the unit is arranged such that it receives each of the three phases from 6 lines.

9. A method comprising:
providing a power supply bus;
connecting at least one three phase power supply line to the bus for supplying current thereto;
connecting at least one three phase power feeder line to the bus for receiving current therefrom;
locating between a respective one of the supply and feeder lines and the bus a respective one of a plurality of circuit breakers for disconnecting flow of current therebetween;
providing a plurality of current sensors each responsive to the three phase current flow between the bus and a respective one of the supply and feeder lines to provide three outputs indicative of the A-phase, B-phase and C-phase respectively of the three phase current flow;
providing a voltage sensor responsive to the voltage on the bus to provide a voltage output indicative thereof;
providing a first, a second and a third separate monitoring and control units for the bus;
providing on each of the units a plurality of current input terminals;
connecting to the current input terminals of the first unit a respective one of the A-phase outputs of the current sensors;
connecting to the current input terminals of the second unit a respective one of the B-phase outputs of the current sensors;
connecting to the current input terminals of the third unit a respective one of the B-phase outputs of the current sensors;
providing on each of the units a voltage input terminal and connecting thereto the voltage output of the voltage sensor;
in each of the units generating digital data indicative of the instantaneous values of the voltage and of the currents in response to the outputs from the terminals connected thereto;
in each of the units effecting pre-determined algorithmic calculations on the digital values of the voltage and the currents to determine a presence of a fault condition in the current through any one of the breakers;
in the first unit summing the digital values of the currents to determine that for the A-phase the sum of currents flowing into the bus and the sum of currents flowing from the bus is equal to zero;
in the second unit summing the digital values of the currents to determine that for the B-phase the sum of currents flowing into the bus and the sum of currents flowing from the bus is equal to zero;
in the third unit summing the digital values of the currents to determine that for the C-phase the sum of currents flowing into the bus and the sum of currents flowing from the bus is equal to zero;
in each of the units generating a fault condition in the event that the sum is not equal to zero;
in each of the units generating a trip output in response to said fault condition for tripping all the circuit breakers associated with bus;
and recording data relating to said current values in the event of a fault condition.

10. The method according to claim 9 wherein each unit has at least 18 current input terminals for receiving one of the phases from the same number of lines.
